(19) United States
(12) Patent Application Publication
(10) Pub. No.: US 2026/0259260 A1
(43) Pub. Date: Sep. 3, 2026

(54) BUILT-IN SELF-TEST ARRANGEMENT FOR A DIGITAL-TO-ANALOG CONVERTER

(71) Applicant: Infineon Technologies AG, Neubiberg (DE)

(72) Inventors: Rocco Calabro, Arnoldstein (AT); David Schaffenrath, Villach (AT); Philipp Wanz, Treffen (AT)

(21) Appl. No.: 19/381,377

(22) Filed: Nov. 6, 2025

(30) Foreign Application Priority Data
Nov. 14, 2024 (DE) 102024133294.8

(51) Int. Cl. G01R 31/317

(52) U.S. Cl. CPC G01R 31/31724; G01R 31/31703

(57) ABSTRACT

A built-in self-test for a DAC, comprising a main DAC, a sub-DAC configured to convert a digital input signal, a comparator configured to compare the output signal of the main DAC with the output signal of the sub-DAC, and a processing unit. The processing unit is configured to determine a coupling factor between the main DAC and the sub-DAC that reflects a ratio of the LSB of the main DAC and the sub-DAC, determine a difference between two sets of bits of the main DAC for N sets of bits by performing a measurement of the main DAC by the sub-DAC based on the coupling factor, wherein N is the number of bits of the main DAC, thereby determining a linear system, determine a bit value for each bit of the main DAC, resolving the linear system, and determine a performance of the main DAC using the determined bit values.

### REFERENCE TO RELATED APPLICATION

This Application claims the benefit of German Application number 102024133294.8, filed on November 14, 2024, the contents of which are hereby incorporated by reference in their entirety.

### FIELD

The present disclosure relates to a built-in self-test (BIST) arrangement for a digital-to-analog converter (DAC) in particular a switched capacitor (SC) successive-approximation register (SAR) analog-to-digital converter (ADC) comprising the BIST arrangement, and a method for performing the BIST.

### BACKGROUND

Data converters usually make use of some sort of digital-to-analog converter DAC, which could be affected by production defects or could be damaged during their lifetime. In production test and in safety relevant applications, it is important to detect these faults, hence a method for the self-test of such DAC is needed.

Currently DAC circuitry can be tested in different way depending in which system they are implemented. Some known methods are the following:

A first test is referred to as Ramp/sinewave test: This test checks the DAC characteristic against a precise reference signal. This approach is usually time consuming and requires a measurement instrument with higher precision compared to the device under test.

Consequently, there is a need for an improved BIST arrangement of a DAC.

### SUMMARY

According to an aspect of the invention, a built-in self-test, BIST, arrangement for a digital-to-analog converter, DAC, comprises the following. A main DAC, configured to convert a digital input signal, received at its input, into an analog output signal, provided at its output. A sub-DAC, configured to convert a digital input signal, received at its input, into an analog output signal, provided at its output. A comparator, coupled to the output of the main DAC and the output of the sub-DAC and configured to compare the analog output signal of the main DAC with the analog output signal of the sub-DAC. A processing unit, coupled to an output of the comparator, the input of the main DAC and the input of the sub-DAC and configured to determine a coupling factor between the main DAC and the sub-DAC by performing a measurement of a plurality of LSBs of the main DAC by the sub-DAC, wherein the coupling factor reflects a ratio of the least significant bit (LSB) of the main DAC and the LSB of the sub-DAC. The processing unit is further configured to determine a difference between two sets of bits of the main DAC for N sets of bits by performing a measurement of the main DAC by the sub-DAC based on the coupling factor, wherein N is the number of bits of the main DAC, thereby determining a linear system. The processing unit is further configured to determine a bit value for each bit of the main DAC, resolving the linear system. The processing unit is further configured to determine a performance of the main DAC using the determined bit values.

In other words, performance and functionality of a DAC, the main DAC, is assessed by using a sub-DAC to resolve a difference between the DAC bits and back-calculate the ratio of its bits. This is basically achieved by determining a coupling factor between the main DAC and the sub-DAC, resolving the difference between two sets of the main DAC bits using the sub-DAC, repeating the aforementioned measurement for N sets of linearly independent bits, where N is the number of bits of the DAC, resolving the linear system and getting the individual bit size of the main DAC, and estimating a functionality and a performance of the main DAC.

The coupling factor, being the ratio of the main DAC LSB and the sub- DAC LSB, enables the sub-DAC to measure the main DAC.

A digital-to-analog converter, DAC, refers to an electronic component, which generally converts a digital input signal, which comprises a number of input lines, to an analog output signal. The number of input lines may indicate a resolution of the DAC. The analog output signal may be a current or may be a voltage, particularly when a high output impedance is desired. The voltage range of the DAC may depend on its specified purpose. An example of an output voltage range may stretch from 0 V to 5 V or, for a differential output, from –5 V to +5 V.

A comparator refers to an electronic component, which compares two input voltages or currents and outputs a digital signal indicating which is larger.

Determining the performance of the main DAC may comprise checking a pass/fall criteria for the determined bit values. In other words, it is determined, for each determined bit value, if the bit value is within a predetermined, expected, range.

The two sets of bits of the main DAC may comprise a first set of bits consisting of only 1 bit of the main DAC and a second set of bits consisting of equivalent sum of bits with lower significance. In general, the two sets of bits may comprise any set of bits which allows the overall system of equations to be linearly independent and allow the difference of the two sets to be in the range of the sub-DAC.

Resolving the linear system may comprise a multiplication of known bit values of the main DAC with the determined differences between the sets of bits of the main DAC. In particular, the system may be resolved by multiplying an inverse matrix of the used set of bits, or in other words sets of equations, by a difference estimated by the sub-DAC, in particular normalized by the coupling factor.

The BIST arrangement can be implemented without the need for additional components, in particular analog circuitry. In other words, the BIST arrangement can be embodied in every system where a main DAC, a sub-DAC, which could also be implemented with the least significant bits (LSB) of the main DAC, and a comparator are available. One example for this is a switched capacitor (SC) successive-approximation register (SAR) analog-to-digital converter (ADC). In the SC SAR ADC, a main DAC and comparator which are used for the ADC conversion and a sub-DAC, which is used for calibration purposes are available.

Furthermore, the BIST arrangement does not require an accurate additional instrument. The relationship between the main DAC and the sub-DAC is accurate enough to estimate a functionality and a performance of the main DAC.

In addition, the self-test may be implemented by a relatively simple digital implementation. The determination of the coupling factor, the determination of the bits of the main DAC, the resolving of the linear system and the determination of the performance of the main DAC do only require a relatively simple control logic of the processing unit.

In addition, the self-test due to its nature has a relatively constant and as such predictable execution time. Compared to the known methods, the self-test also has a faster execution time, in particular a plurality of times faster than the known methods.

Due to the fast execution time and its relatively simple digital implementation, the processing unit can be implemented on-chip. This provides more resilience to measurement noise.

Consequently, the BIST arrangement allows for a very quick, precise, and cheap way to detect defects and failures of a main DAC circuit, in particular after its manufacturing and during its lifetime.

Thus, an improved BIST arrangement of a DAC is provided.

In one example, the processing unit is configured to measure the sub-DAC using the main DAC, thereby assessing the functionality and performance of the sub-DAC.

In other words, the main DAC is used to measure the sub-DAC and assess if the sub-DAC is functioning with the correct sizing. Thus, the DAC is used to assess functionality and performance, in particular an approximate performance, of the sub-DAC.

The resolution of the main DAC may be smaller than the resolution of the sub-DAC. In this case the main DAC is only able to perform a rough measurement of the sub-DAC. Consequently, measuring the sub-DAC using the main DAC may identify a sub-DAC with major defects.

Thus, it can be assured with a relatively high probability that the sub-DAC is working properly. This is important, as the sub-DAC is used to measure the main DAC and to test the main DAC.

Thus, an improved BIST arrangement of a DAC is provided.

In one example, the measurement of the main DAC by the sub-DAC is performed in two directions, thereby ignoring an offset of the comparator.

In general, a comparator comprises an offset value, also referred to as offset voltage that needs to be applied to the input of the comparator to create an output voltage of 0V. In order to provide an offset free output voltage of the comparator, the measurement of the main DAC by the sub-DAC, namely the determining of the coupling factor and the determining of the difference between two sets of the main DAC bits, is performed in two directions, or in other words in inverted directions. In other words, each measurement of the main DAC is performed two times with switched inputs to the main DAC. The results of those measurements are then added up and divided by two in order to receive an offset free result. Consequently, the offset of the comparator does not have to be measured otherwise and be considered in the measurements and calculations.

Thus, an improved BIST arrangement of a DAC is provided.

In one example, performing the measurement of the main DAC by the sub-DAC comprises performing a Successive Approximation Register (SAR) search.

The SC SAR ADC already comprises a main DAC and comparator which are used for the ADC conversion and a sub-DAC which is used for calibration purposes. Consequently, in an SC SAR ADC circuit, the described BIST arrangement can be implemented without the need for additional components.

Thus, a BIST arrangement of a DAC with improved precision of the measurement of the main DAC is provided.

In one example, determining the difference between two sets of bits of the main DAC comprises performing averaging of the determined difference.

Averaging, which is also referred to as signal averaging or averaging algorithm, refers to a method that reduces a noise component of a signal, or in other words that enhances a signal-to-noise ratio of the signal. In other words, averaging reduces the impact of noise to a measured signal, in this case the difference between two sets of bits of the main DAC. In particular, averaging mitigates noise caused by mismatch in the digital-to-analog conversion.

Thus, a BIST arrangement of a DAC with improved precision of the measurement of the main DAC is provided.

In one example, determining a performance of the main DAC comprises estimating a differential nonlinearity (DNL) or an integral nonlinearity (INL) of the main DAC.

Although the performance of the main DAC can be determined based on the determined bit values of the main DAC only, the DNL or the DAC provide measurement methods, which are used for determining a performance of a DAC.

The DNL describes a deviation between pairs of bit values compared to an ideal LSB step.

The DAC describes a deviation between an ideal DAC transfer function, which is a straight line, compared to the DAC transfer function determined by the bit values of the main DAC.

In one example, the sub-DAC comprises a higher resolution than the main DAC.

A difference between two sets of bits of the main DAC for N sets of bits is determined by performing a measurement of the main DAC by the sub-DAC. Thus, due to the relatively high resolution of the sub-DAC, being higher than the resolution of the main DAC, a relatively high precision of the measurement of the main DAC can be achieved.

In particular, due to the relatively small range that the sub-DAC needs to have, a sub-DAC with focus on a high resolution can be chosen for the BIST arrangement without significantly raising the costs of the BIST arrangement.

Thus, a BIST arrangement of a DAC with improved precision of the measurement of the main DAC is provided.

Providing a BIST arrangement with a sub-DAC with relatively high resolution and using averaging when measuring the main DAC using the sub-DAC further improves the precision of the measurement of the main DAC.

In one example, the sub-DAC comprises less range than the main DAC.

For the measurement of the main DAC, the sub-DAC does not need to have the same range than the main DAC, in particular due to the determination of the coupling factor. This allows the sub-DAC to have a higher resolution compared to a sub-DAC with a larger range.

Thus, a BIST arrangement of a DAC with improved precision of the measurement of the main DAC is provided.

In one example, the sets of bits of the main DAC are linearly independent.

In order to resolve a linear system with N variables, at least N equations which are linearly independent are needed. In this system the equations are the sets of bits which are used for the measurements and the variables are the bits that should be determined.

In one example, the sub-DAC is implemented using a plurality of LSBs of the main DAC.

In other words, without the necessity of a structural sub-DAC, a plurality of LSBs of the main DAC can be used for performing the measurement of the main DAC.

Thus, a BIST arrangement of a DAC with reduced components is provided.

In one example, the BIST arrangement is integrated into one semiconductor chip.

Due to the simplicity of the method for performing the BIST, the processing unit can be implemented directly on chip.

Thus, a compact implementation of the BIST arrangement is provided.

According to an aspect of the invention, a switched capacitor (SC) successive-approximation register (SAR) analog-to-digital converter (ADC) is provided, comprising the BIST arrangement, as described herein.

One example for this is a switched capacitor (SC) SAR ADC. In this specific circuit a main DAC and comparator which are used for the ADC conversion and a sub-DAC which is used for calibration purposes are available.

According to an aspect of the invention, a method is provided for performing a built-in self-test, BIST for a digital-to-analog converter (DAC) comprising a main DAC, configured to convert a digital input signal, received at its input, into an analog output signal, provided at its output, a sub-DAC, configured to convert a digital input signal, received at its input, into an analog output signal, provided at its output, wherein the sub-DAC comprises less range than the main DAC, a comparator being coupled to the output of the main DAC and the output of the sub-DAC and configured to compare the analog output signal of the main DAC with the analog output signal of the sub-DAC and a processing unit is coupled to an output of the comparator, the input of the main DAC and the input of the sub-DAC. The method comprises the following steps. Determining a coupling factor between the main DAC and the sub-DAC by performing a measurement of a plurality of LSBs of the main DAC by the sub-DAC, wherein the coupling factor reflects a ratio of the least significant bit, LSB, of the main DAC and the LSB of the sub-DAC. Determining a difference between two sets of bits of the main DAC for N sets of bits by performing a measurement of the main DAC by the sub-DAC, wherein N is the number of bits of the main DAC, thereby determining a linear system. Determining a bit value for each bit of the main DAC, resolving the linear system. Determining a performance of the main DAC using the determined bit values.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates an example BIST arrangement for a DAC;

FIG. 2 illustrates an example method for performing a BIST for a DAC;

FIG. 3 illustrates an example of a circuit for determining a coupling factor in a BIST arrangement for a DAC; and

FIG. 4 illustrates an example of a circuit for determining a difference between two sets of bits of the main DAC.

### DETAILED DESCRIPTION

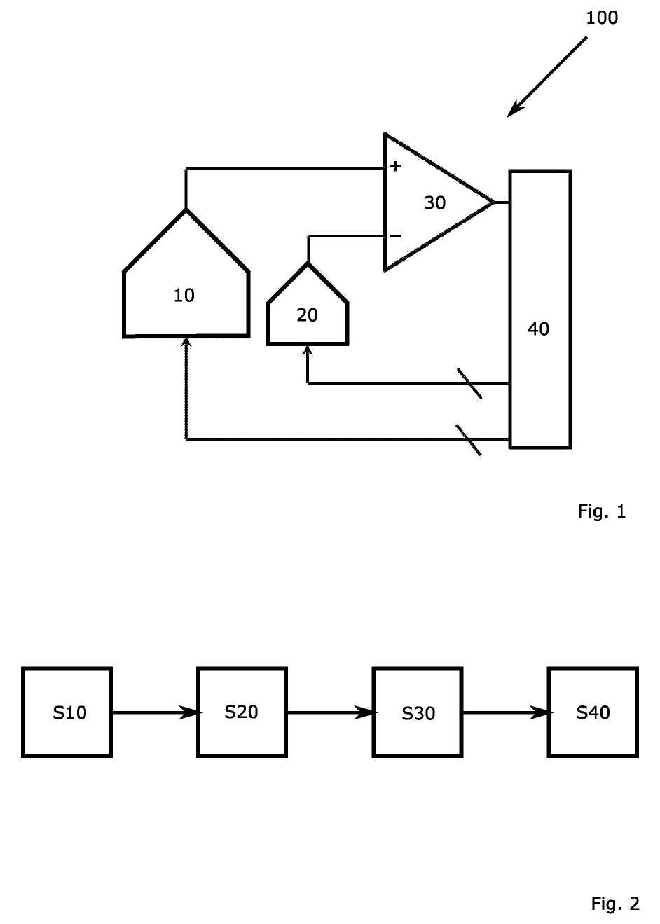

FIG. 1 illustrates a built-in self-test (BIST) arrangement 100 for a digital-to-analog converter (DAC) comprising the following: a main DAC 10, configured to convert a digital input signal, received at its input, into an analog output signal, provided at its output; a sub-DAC 20, configured to convert a digital input signal, received at its input, into an analog output signal, provided at its output; and a comparator 30, coupled to the output of the main DAC 10 and the output of the sub-DAC 20 and configured to compare the analog output signal of the main DAC 10 with the analog output signal of the sub-DAC. The comparator 30 comprises a positive input + and a negative input -, wherein the main DAC is connected to the positive input + and the sub-DAC is connected to the negative input -. A processing unit 40, is coupled to an output of the comparator 30, the input of the main DAC 10 and the input of the sub-DAC 20. The processing unit 40 is configured to control the main DAC and the sub-DAC.

The processing unit 40 is configured to determine a coupling factor between the main DAC 10 and the sub-DAC 20 by performing a measurement of a plurality of LSBs of the main DAC 10 by the sub-DAC 20, wherein the coupling factor reflects a ratio of the least significant bit (LSB) of the main DAC 10 and the LSB of the sub-DAC 20, determine a difference between two sets of bits of the main DAC 10 for N sets of bits by performing a measurement of the main DAC 10 by the sub-DAC 20 based on the coupling factor, wherein N is the number of bits of the main DAC 10, thereby determining a linear system, determine a bit value for each bit of the main DAC 10, resolving the linear system, and determine a performance of the main DAC 10 using the determined bit values.

FIG. 2 illustrates a method for performing a BIST for a digital-to-analog converter (DAC) comprising a main DAC 10, configured to convert a digital input signal, received at its input, into an analog output signal, provided at its output, a sub-DAC 20, configured to convert a digital input signal, received at its input, into an analog output signal, provided at its output, wherein the sub-DAC 20 comprises less range than the main DAC 10, a comparator 30 being coupled to the output of the main DAC 10 and the output of the sub-DAC 20 and configured to compare the analog output signal of the main DAC 10 with the analog output signal of the sub-DAC 20 and a processing unit is coupled to an output of the comparator, the input of the main DAC 10 and the input of the sub-DAC 20, wherein the method comprises the following steps.

One step S10 comprises determining a coupling factor between the main DAC 10 and the sub-DAC 20 by performing a measurement of a plurality of LSBs of the main DAC 10 by the sub-DAC 20, wherein the coupling factor reflects a ratio of the least significant bit (LSB) of the main DAC 10 and the LSB of the sub-DAC 20. Another step S20 comprises determining a difference between two sets of bits of the main DAC 10 for N sets of bits by performing a measurement of the main DAC 10 by the sub-DAC 20, wherein N is the number of bits of the main DAC 10, thereby determining a linear system. Another step S30 comprises determining a bit value for each bit of the main DAC 10, resolving the linear system. Another step S40 comprises determining a performance of the main DAC using the determined bit values.

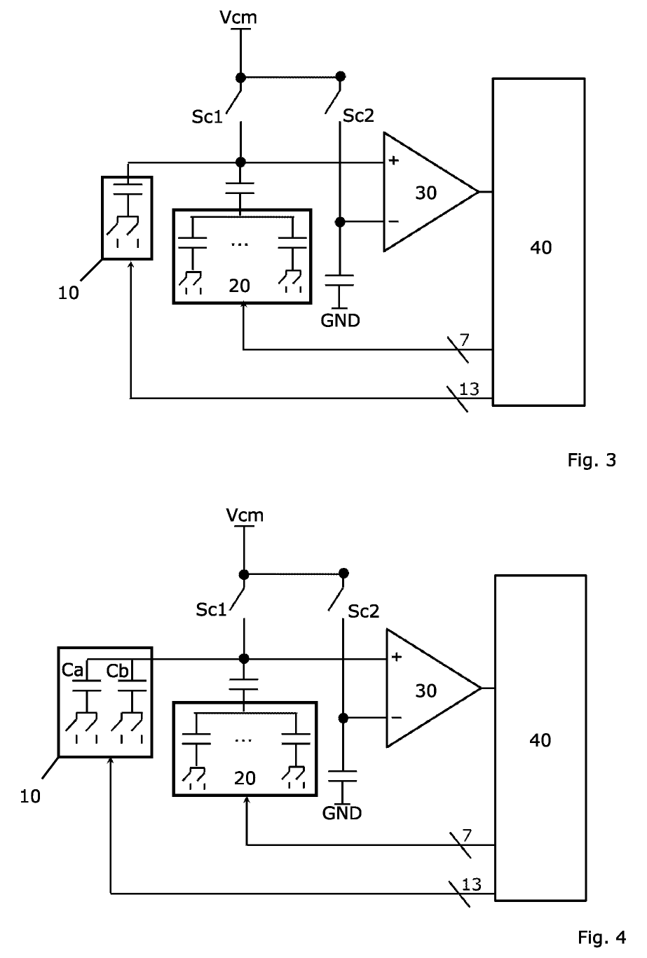

FIG. 3 illustrates determining a coupling factor in a BIST arrangement for a DAC.

In general, the structure of the BIST arrangement is in line with the BIST arrangement of FIG. 1. However, the BIST arrangement of FIG. 3 is implemented in an SC SAR ADCs, wherein the comparator 30 successively compares an input voltage to the output of an internal DAC using switching capacitors. Consequently, the main DAC 10 and the sub-DAC 20 comprise a plurality of capacitors, connected to each other in parallel. Each of the capacitors can be connected to either a positive or ground reference. In this case, the main DAC 10 has a range of 13 bits and the sub-DAC 20 has a range of 7 bits. The comparator 30 comprises a positive input + and a negative input -. The negative input - is connected between ground GND and a common mode voltage Vcm. Between the common mode voltage Vcm and the negative input -, a second common mode switch Sc2 is disposed. Between the negative input - and the ground GND, a capacitor is disposed. The positive input + is connected to the outputs of the main DAC 10 and the sub-DAC 20, which are connected to the common mode voltage Vcm via a first common mode switch Sc1.

The coupling factor between the main DAC 10 and the sub-DAC 20 is determined by performing a measurement of a plurality of LSBs of the main DAC 10 by the sub-DAC 20. In one step, the so called sampling phase, a capacitor of the main DAC 10, for example the LSB+2 capacitor is connected to the ground reference voltage. The first and second common mode switches Sc1, Sc2 are closed.

In another step, the so called conversion phase, the common mode switches Sc1 and Sc2 are open and the capacitor of the main DAC 10 is connected to a reference voltage. A SAR search is performed on the main DAC 10 by the sub-DAC 20, or in other words the sub-DAC 20 measures the main DAC 10.

The search is then performed for N times, where N is the number of wished conversions to be averaged and an average result of the search is determines a positive coupling factor.

In another step, another sampling phase is performed, wherein the capacitor of the main DAC 10 is connected to the reference voltage.

Consequently, in another step, the conversion phase is performed, wherein the capacitor of the main DAC 10 is connected to the ground reference voltage. A SAR search is performed on the main DAC 10 by the sub-DAC 20, or in other words the sub-DAC 20 measures the main DAC 10.

The search is then performed for N times, wherein where N is the number of wished conversions to be averaged and an average result of the search is determines a negative coupling factor.

Subtracting the negative coupling factor from the positive coupling factor and dividing the results by 2, or in case of the LSB+2 capacitor by 2 times 2², the offset free coupling factor is determined.

FIG. 4 illustrates determining a difference between two sets of bits of the main DAC.

In this example, each bit of the main DAC and the sub-DAC is represented by a capacitor. Consequently, the difference between a first set of capacitors Ca and a second set of capacitors Cb is determined. Preferably, the first set of capacitors Ca comprises one capacitor and the second set of capacitors Cb comprises the equivalent sum of smaller capacitors.

Thus, the difference between the first set of capacitors Ca and the second set of capacitors Cb is determined in the following way.

In one step, the so called sampling phase, the first set of capacitors Ca of the main DAC 10 is connected to a ground reference voltage and the second set of capacitors Cb of the main DAC 10 is connected to a reference voltage. Common mode switches Sc1 and Sc2, connecting a common mode voltage Vcm to the positive input + and the negative input – of the comparator 30, respectively, are closed.

In another step, the so called conversion phase, the common mode switches Sc1 and Sc2 are open and the first set of capacitors Ca of the main DAC 10 is connected to the reference voltage and the second set of capacitors Cb of the main DAC 10 is connected to the ground reference voltage. A SAR search is performed on the main DAC 10 by the sub-DAC 20, or in other words the sub-DAC 20 measures the main DAC 10.

The search is then performed for N times, where N is the number of wished conversions to be averaged and an average result of the search is determines a positive difference.

In another step, another sampling phase is performed, wherein the first set of capacitors Ca of the main DAC 10 is connected to the ground reference voltage and the second set of capacitors Cb of the main DAC 10 is connected to the reference voltage.

Consequently, in another step, the conversion phase is performed, wherein the first set of capacitors Ca of the main DAC 10 is connected to the ground reference voltage and the second set of capacitors Cb of the main DAC 10 is connected to the reference voltage. A SAR search is performed on the main DAC 10 by the sub-DAC 20, or in other words the sub-DAC 20 measures the main DAC 10.

The search is then performed for N times, wherein where N is the number of wished conversions to be averaged and an average result of the search is determined a negative difference.

Subtracting the negative difference from the positive difference and dividing the results by 2, the offset free difference between the two sets of bits of the main DAC 10 is determined.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and arrangements including its preferred embodiments as outlined in the present document may be used stand-alone or in combination with the other methods and arrangements disclosed in this document. In addition, the features outlined in the context of an arrangement are also applicable to a corresponding method, and vice versa. Furthermore, all aspects of the methods and arrangements outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A built-in self-test (BIST) arrangement for a digital-to-analog converter (DAC) comprising:
a main DAC configured to convert a digital input signal, received at its input, into an analog output signal, provided at its output;
a sub-DAC configured to convert a digital input signal, received at its input, into an analog output signal, provided at its output;
a comparator coupled to the output of the main DAC and the output of the sub-DAC and configured to compare the analog output signal of the main DAC with the analog output signal of the sub-DAC;
and a processing unit, coupled to an output of the comparator, the input of the main DAC and the input of the sub-DAC and configured to
determine a coupling factor between the main DAC and the sub-DAC by performing a measurement of a plurality of LSBs of the main DAC by the sub-DAC, wherein the coupling factor reflects a ratio of the least significant bit (LSB) of the main DAC and the LSB of the sub-DAC;
determine a difference between two sets of bits of the main DAC for N sets of bits by performing a measurement of the main DAC by the sub-DAC based on the coupling factor, wherein N is the number of bits of the main DAC, thereby determining a linear system;
determine a bit value for each bit of the main DAC by resolving the linear system; and
determine a performance of the main DAC based on the determined bit values.

2. The BIST arrangement of claim 1, wherein the processing unit is configured to measure the sub-DAC using the main DAC.

3. The BIST arrangement of claim 1, wherein the measurement of the main DAC by the sub-DAC is performed in two directions.

4. The BIST arrangement of claim 1, wherein performing the measurement of the main DAC by the sub-DAC comprises:
performing a Successive Approximation Register (SAR) search.

5. The BIST arrangement of claim 1, wherein determining the difference between two sets of bits of the main DAC comprises:
performing averaging of the determined difference.

6. The BIST arrangement of claim 1, wherein determining a performance of the main DAC comprises:
estimating a differential nonlinearity (DNL) or an integral nonlinearity (INL) of the main DAC.

7. The BIST arrangement of claim 1, wherein the sub-DAC comprises a higher resolution than the main DAC.

8. The BIST arrangement of claim 1, wherein the sub-DAC comprises less range than the main DAC.

9. The BIST arrangement of claim 1, wherein the sets of bits of the main DAC are linearly independent.

10. The BIST arrangement of claim 1, wherein the sub-DAC is implemented using a plurality of LSBs of the main DAC.

11. The BIST arrangement of claim 1, wherein the BIST arrangement is integrated into one semiconductor chip.

12. A method for performing a built-in self-test, BIST for a digital-to-analog converter (DAC) comprising:
determining a coupling factor between a main DAC and a sub-DAC by performing measurement of a plurality of LSBs of the main DAC by the sub-DAC, based on a ratio of the least significant bit, LSB, of the main DAC and the LSB of the sub-DAC;
determining a linear system based on a difference between two sets of bits of the main DAC for N sets of bits by performing a measurement of the main DAC by the sub-DAC based on the coupling factor, wherein N is based on the number of bits of the main DAC;
resolving the linear system to determine a bit value for each bit of the main DAC; and
determining a performance of the main DAC based on the determined bit values.

13. The method of claim 12, comprising:
determining a positive coupling factor by measuring the main DAC with the sub-DAC with a capacitor of the main DAC connected to a reference voltage;
determining a negative coupling factor by measuring the main DAC with the sub-DAC with the capacitor of the main DAC connected to a ground reference voltage; and
determining the coupling factor based on the positive coupling factor and the negative coupling factor.

14. The method of claim 13, wherein the capacitor is associated with the LSB + n bit of the main DAC, the method comprising determining the coupling factor by subtracting the negative coupling factor from the positive coupling factor and dividing the result by 2∙2ⁿ.

15. The method of claim 12, wherein the two sets of bits of the main DAC comprise a first set of bits that includes a single bit of the main DAC representing a value and a second set of bits that includes bits representing respective values whose sum is equivalent to the value.

16. The method of claim 12, comprising determining the difference between the two sets of bits by, for each of the two sets of bits,
connecting capacitors associated with a first set of bits to a reference voltage and capacitors associated with a second set of bits to a ground reference voltage;
making at least one measurement of the difference between the first set of bits and the second set of bits to determine a positive difference;
connecting the capacitors associated with the first set of bits to the ground reference voltage and the capacitors associated with the second set of bits to the reference voltage;
making at least one measurement of the difference between the first set of bits and the second set of bits to determine a negative difference; and
determining an offset free difference between the two sets of bits as half the difference between the positive difference and the negative difference.

17. The method of claim 12, comprising measuring the main DAC with the sub-DAC by performing a Successive Approximation Register (SAR) search.

18. The method of claim 12, further comprising measuring the sub-DAC using the main DAC to determine whether the sub-DAC is functioning properly.

19. The method of claim 12, wherein the sub-DAC is implemented using a plurality of LSBs of the main DAC.

20. The method of claim 12, wherein the sub-DAC comprises less range than the main DAC.
